(19) United States
(12) Patent Application Publication
(10) Pub. No.: US 2023/0078536 A1
(43) Pub. Date: Mar. 16, 2023

(54) CONDUCTIVE FEATURES ON SYSTEM-IN-PACKAGE SURFACES

(71) Applicant: Apple Inc., Cupertino, CA (US)

(72) Inventors: Ali N. Ergun, Sunnyvale, CA (US); Bilal Mohamed Ibrahim Kani, Singapore (SG); Chang Liu, San Jose, CA (US); Ethan L. Huwe, Davis, CA (US); Jeffrey J. Terlizzi, San Francisco, CA (US); Jerzy S. Guterman, Sunnyvale, CA (US); Jue Wang, San Jose, CA (US); Kishore N. Renjan, Singapore (SG); Kyusang Kim, Singapore (SG); Lan H. Hoang, San Jose, CA (US); Mandar S. Painaik, Cupertino, CA (US); Manoj Vadeentavida, Singapore (SG); Sarah B. Gysbers, Santa Clara, CA (US); Takayoshi Katahira, San Jose, CA (US); Zhiqi Wang, Shanghai (CN)

(73) Assignee: Apple Inc., Cupertino, CA (US)

(21) Appl. No.: 17/832,346

(22) Filed: Jun. 3, 2022

Related U.S. Application Data
(60) Provisional application No. 63/243,892, filed on Sep. 14, 2021.

(51) Int. Cl. H05K 1/02; H05K 1/11; H01Q 1/22; H01Q 1/36

(52) U.S. Cl. CPC H05K 1/0243; H05K 1/11; H01Q 1/22; H01Q 1/36; H05K 2201/10098

(57) ABSTRACT

System-in-package modules that can provide a high level of functionality, are space efficient, and are readily manufactured. In an example, a high-functionality system-in-package module can include both a wireless circuit and an antenna. In an example, a space-efficient system-in-package module can include different vertical interconnect paths that can be used to connect the wireless circuit to the antenna. In an example, instead of being shaped as a traditional rectangular cuboid, a space-efficient system-in-package module can have a shape that more closely matches contours of an enclosure for an electronic device.

### CROSS-REFERENCES TO RELATED APPLICATIONS

This application is a continuation of U.S. patent application No. 63/243,892, filed Sep. 14, 2021, which is incorporated by reference.

### BACKGROUND

The number of types of electronic devices that are commercially available has increased tremendously the past few years and the rate of introduction of new devices shows no signs of abating. Devices, such as portable computing devices, tablet, laptop, netbook, desktop, and all-in-one computers, smart phones, wearable computing devices, storage devices, portable media players, navigation systems, monitors, power adapters, and others, have become ubiquitous.

The functionality of these devices has likewise greatly increased. This in turn has led to increased complexity inside of these electronic devices. At the same time, the dimensions of these devices have become smaller. For example, smaller and thinner devices are always popular.

This increasing functionality and decreasing size have necessitated the use of space-efficient circuit techniques. As one example, system-in-package modules and other similar structures can be used to increase an electronic device's functionality while reducing space consumed in the device. While these techniques have proved useful, it would be desirable to be able to pack more functionality in system-in-package modules. Having higher capability modules would allow an increase in an amount of functionality for a given volume in an electronic device.

It would also be desirable to increase the space-efficiency provided by system-in-package modules. Decreasing the size of system-in-package modules would help to reduce the size of the electronic devices housing such modules.

The electronic devices housing these system-in-package modules can become very popular and can be sold in large volumes. Accordingly, it can be desirable to have improved system-in-package modules that can be readily manufactured.

Thus, what is needed are system-in-package modules that can provide a high level of functionality, are space efficient, and are readily manufactured.

### SUMMARY

Accordingly, embodiments of the present invention can provide system-in-package modules that can provide a high level of functionality, are space efficient, and are readily manufactured.

These and other embodiments of the present invention can provide system-in-package modules having a high level of functionality. In an example, a high-functionality system-in-package module can include both a wireless circuit and an antenna. This system-in-package module can be formed of an integrated circuit mounted on a board, where the board can be a flexible circuit board, printed circuit board, or other board. The integrated circuit can be a wireless receiver, wireless transmitter, wireless transceiver, or other RF or other type of wireless or other integrated circuit (referred to here as wireless circuit for simplicity.) A molding layer or encapsulation can be over a top surface of the board. The encapsulation can be at least over the integrated circuit and can encapsulate the integrated circuit. An antenna for the wireless circuit can be formed on a surface of the system-in-package module, for example on a top surface, thereby increasing the functionality of the module.

These and other embodiments of the present invention can provide space-efficient system-in-package modules. In an example, a space-efficient system-in-package module can include different vertical interconnect paths can be used to connect the wireless circuit to the antenna. For example, a stack of molten solder or sinter drops can be used to form a path from a contact on a top surface of the board to the antenna. Pins can be used to form paths from a contact on a top surface of the board to the antenna. Bond wires or other wires can form a path from a contact on a top surface of the board to the antenna. A trace through the board can connect a pin to the wireless circuit.

In an example, instead of being shaped as a traditional rectangular cuboid, a space-efficient system-in-package module can have a shape that more closely matches, or at least partially conforms to, contours of an enclosure for an electronic device. These and other embodiments of the present invention can also save space in an electronic device by providing system-in-package modules that have one or more surfaces that at least partially conform to an interior surface, structure, partition, or other portion of an electronic device. As a result, a system-in-package module can have one or more curved surfaces. For example, a surface of a system-in-package module where an antenna is formed can be curved.

These and other embodiments of the present invention can include other components, on a board, on a surface of an encapsulation, or elsewhere in a system-in-package module. This inclusion can increase a functionality of system-in-package module. This inclusion can also save space in an electronic device when an included component replaces a separate component that would otherwise be needed. For example, sensor electrodes, charging coils, transformers, shields, inductors, capacitors, resistors, and other components can be formed on a board, on a surface of an encapsulation, or elsewhere in a system-in-package module. Two or more encapsulation layers can be stacked to bring even further functionality to a system-in-package module. For example, a first encapsulation can be formed over a board. A shield or other component can be formed on a surface of the first encapsulation. Additional electronic components, such as resistors, capacitors, active components, integrated circuits, or others can be added to or formed on the surface of the first encapsulation. Connections between the board and these components can be made through pins. A second encapsulation can be formed over the first encapsulation. An antenna or other component can be formed on a surface of the second encapsulation. Additional electronic components, such as resistors, capacitors, active components, integrated circuits, or others can be added to or formed on the surface of the second encapsulation. Connections between the board and these components, and between these components and components on the surface of the first encapsulation, can be made through pins. A surface of the first encapsulation can be flat or planar, or it can be curved. A surface of the second encapsulation can be flat or planar, or it can be curved. Stacking of encapsulations can be facilitated by employing a thermoset plastic for at least the first encapsulation, since this material might not re-melt when the second encapsulation is formed.

These and other embodiments of the present invention can provide system-in-package modules that can be readily manufactured. In an example, the pins can be surface-mount pins that can be attached to a board using surface-mount technology methods. The antenna can be formed in various ways. For example, the antenna can be formed of a copper foil layer attached to a surface of the system-in-package module with an adhesive layer. The copper foil layer can be a rolled-annealed copper layer. The adhesive layer can be a pressure-sensitive adhesive layer, a heat-activated film layer, a polyimide film or other adhesive layer. The antenna can be formed using a conductive epoxy paste. The antenna can be formed using printing, such as pad printing, stencil printing, ink-jet printing, physical vapor deposition, plating, or method. The antenna can be printed in a pattern optimized for signal reception. The encapsulation can be formed of various materials. For example, the encapsulation can be formed of epoxy molding compounds. This material is particularly useful when an antenna is printed on a surface of the system-in-package module. The encapsulation can be formed of a liquid crystal polymer. This material is particularly useful when an antenna is plated on a surface of the system-in-package module. The encapsulation can be formed using Laser Direct Structuring (LDS) and an epoxy molding compound. The antenna can then be formed by activating a surface of the encapsulation with a laser and then plating. The pins can be attached to the antenna in various ways. For example, the encapsulation can be formed such that a top portion of each pin remains exposed. When the antenna is formed, it can be physically and electrically connected to the top portion of each pin. The encapsulation can be formed such that a top portion of each pin is covered by the encapsulation. The encapsulation over the top portion of each pin can be etched, laser ablated, or otherwise removed, thereby leaving the top portion of each pin exposed where it can be physically and electrically connected to the antenna when the antenna is formed.

It should be noted that while the structures and methods described here are well-suited to forming system-in-package modules, in other embodiments of the present invention, other types of electronic devices can be formed using these techniques. Embodiments of the present invention can be used at different levels in the manufacturing of a system-in-package module.

For example, a system-in-package module can be formed of one or more other sub-modules, and these embodiments of the present invention can be used in one or more of these sub-modules. The system-in-package module itself can be formed by employing one or more embodiments of the present invention.

In various embodiments of the present invention, pins and other conductive portions of the system-in-package modules can be formed by stamping, metal-injection molding, machining, micro-machining, 3-D printing, or other manufacturing process. The conductive portions can be formed of stainless steel, steel, copper, copper titanium, aluminum, phosphor bronze, or other material or combination of materials. They can be plated or coated with nickel, gold, or other material. The nonconductive portions can be formed using insert, injection, overmolding, or other molding, 3-D printing, machining, or other manufacturing process. The nonconductive portions can be formed of silicon or silicone, rubber, hard rubber, plastic, nylon, liquid-crystal polymers, or other nonconductive material or combination of materials. The printed circuit board or other appropriate substrates used can be formed of FR-4, BT or other material. Printed circuit boards can be replaced by other substrates, such as flexible circuit boards, in many embodiments of the present invention, while flexible circuit boards can be replaced by printed circuit boards in these and other embodiments of the present invention.

Embodiments of the present invention can provide system-in-package modules that can be located in various types of devices, such as portable computing devices, tablet computers, desktop computers, laptops, all-in-one computers, wearable computing devices, smart phones, storage devices, portable media players, navigation systems, headphones, earbuds, speakers, or other audio components, monitors, power supplies, adapters, remote control devices, chargers, and other devices.

Various embodiments of the present invention can incorporate one or more of these and the other features described herein. A better understanding of the nature and advantages of the present invention can be gained by reference to the following detailed description and the accompanying drawings.

### BRIEF DESCRIPTION OF THE DRAWINGS

FIG. 1 is a simplified transparent view of a system-in-package module according to an embodiment of the present invention;

FIG. 2A through FIG. 5E illustrate methods of manufacturing system-in-package modules according to embodiments of the present invention;

FIG. 6 illustrates a portion of an electronic device according to an embodiment of the present invention;

FIG. 7 is a simplified transparent view of a system-in-package module according to an embodiment of the present invention; and

FIG. 8 illustrates a cutaway side view of an electronic device incorporating the system-in-package module of FIG. 7.

### DESCRIPTION OF EXEMPLARY EMBODIMENTS

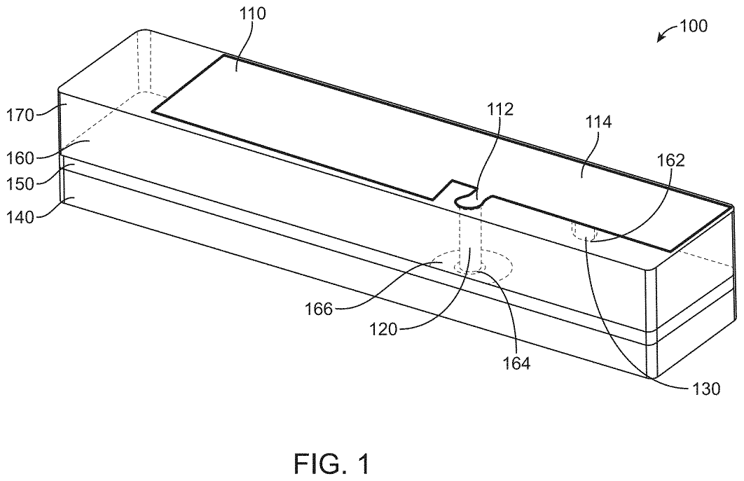

FIG. 1 is a simplified transparent view of a system-in-package module according to an embodiment of the present invention. This figure, as with the other included figures, is shown for illustrative purposes and does not limit either the possible embodiments of the present invention or the claims.

In this example, antenna 110 can be included a part of system-in-package module 100. This inclusion can increase a functionality of system-in-package module 100. This inclusion can also save space in an electronic device since a separate antenna might not be required.

System-in-package module 100 can be formed on board 140. Board 140 can be a printed circuit board, flexible circuit board, or other appropriate substrate. Board 140 can be formed of multiple layers and can include ground planes, power planes, and electrical interconnect paths formed of horizontal traces and vertical vias (not shown.) One or more plated layers 150 can be formed on board 140. In this example, one or more plated layers 150 can form contact 164, which can be separated from ground plane 160 on a top surface of board 140 by opening 166. Molding layer or encapsulation 170 can be formed over the top surface of board 140. Antenna 110 can be formed on a top surface of encapsulation 170.

Pin 120 and pin 130 can electrically connect antenna 110 to interconnect paths in board 140. Pin 120 can be used as a portion of a feeder path and can electrically connect to antenna 110 at location 112. Pin 120 can be soldered to contact 164 on a top surface of board 140. Contact 164 can in turn be connected to an interconnect path in board 140. Pin 130 can be used as a portion of a ground path and can electrically connect to antenna 110 at location 114. Pin 130 can be soldered to ground plane 160 at contact 162 on the top surface of board 140. Ground plane 160 can in turn be connected to interconnect paths and ground planes in board 140.

System-in-package module 100 can include additional functionality. For example, system-in-package module 100 can include one or more integrated circuits, one or more other passive or active components, one or more micro electro-mechanical systems, or other types of components. For example, system-in-package module 100 can include one or more integrated circuits including a wireless circuit. This wireless circuit can be a wireless receiver, wireless transmitter, wireless transceiver, or other integrated circuit.

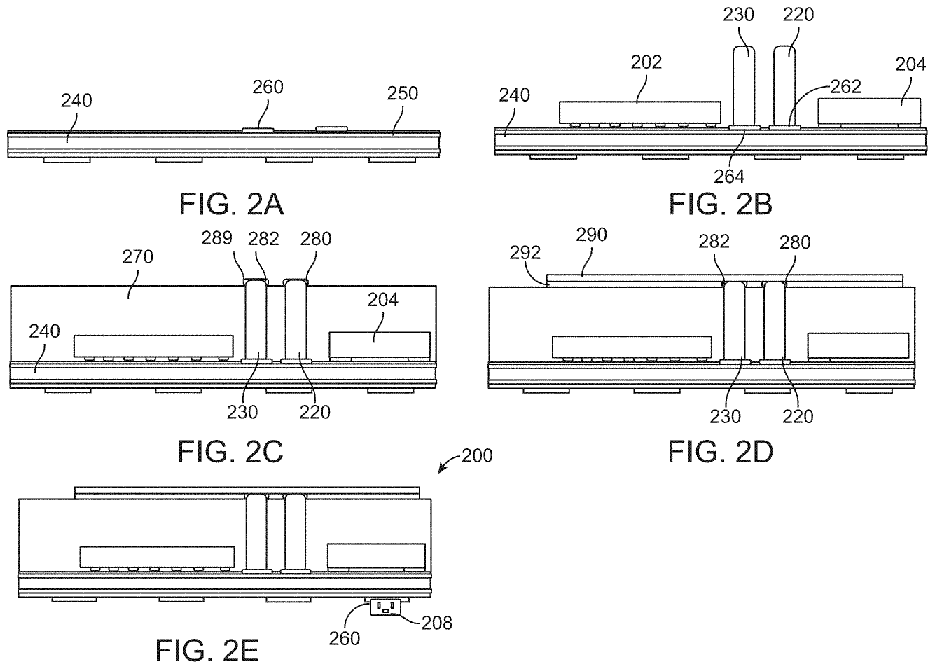

System-in-package module 100 can be manufactured using various methods and materials. For example, antenna 110 can be formed in various ways. Antenna 110 can be formed of a copper foil layer and attached to a surface of system-in-package module with adhesive layer 292 (shown in FIG. 2D.) The copper foil layer can be a rolled-annealed copper layer. Adhesive layer 292 can be a pressure-sensitive adhesive layer, a heat-activated film layer, a polyimide film|or other adhesive layer. Antenna 110 can be formed using conductive epoxy paste. Antenna 110 can be formed using printing, such as pad printing, stencil printing, ink-jet printing, physical vapor deposition, plating, or method. Antenna 110 can be printed in a pattern optimized for wireless signal reception. Pin 120 and pin 130 can be formed as copper pins, though they can be formed of other materials, such as stainless steel, copper alloys, or other materials. A stack of molten solder or sinter drops can be used to form pin 120 and pin 130. A wire bond can be used to form pin 120 and pin 130. Encapsulation 170 can be formed of various materials. For example, encapsulation 170 can be formed of epoxy molding compounds. This material is particularly useful when antenna 110 is printed on a surface of system-in-package module 100. Encapsulation 170 can be formed of a liquid crystal polymer. This material is particularly useful when antenna 110 is plated on a surface of system-in-package module. Encapsulation 170 can be formed using Laser Direct Structuring (LDS) and an epoxy molding compound. Antenna 110 can be formed by activating a surface of encapsulation 170 with a laser and then plating. Pin 220 and pin 230 can be attached to antenna 110 in various ways. For example, encapsulation 170 can be formed such that a top portion of pin and a top portion of pin 130 remains exposed. When antenna 110 is formed, it can be physically and electrically connected to the top portion of pin 120 and the top portion of pin 130. Alternatively encapsulation 170 can be formed such that the top portion of pin 120 and the top portion of pin 130 is covered by encapsulation 170. Encapsulation 170 over the top portion of each pin can be etched, laser ablated, or otherwise removed, thereby leaving the top portion of pin 120 and the top portion of pin 130 exposed where they can be physically and electrically connected to the antenna 110 when antenna 110 is formed. While antenna 110 is shown here, other structures, such as sensor electrodes, charging coils, transformers, shields, inductors, capacitors, resistors, and other components can be formed on a surface of encapsulation 170.

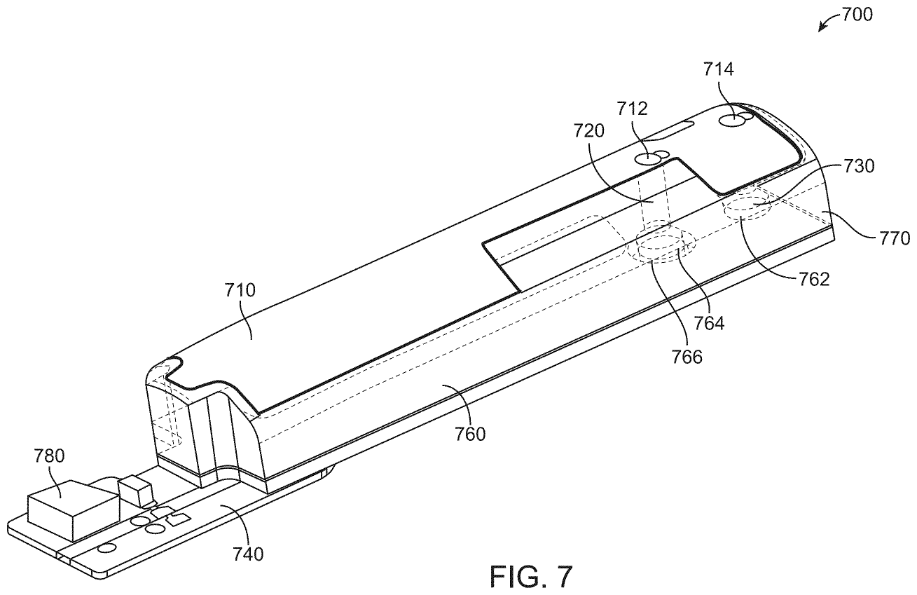

Additional structures can be included in system-in-package module 100 and the other system-in-package modules shown here. For example, one or more additional shielding layers can be included on a surface of system-in-package module 100 to provide low-frequency or other types of shielding. A flexible circuit board can be fixed to a surface of system-in-package module 100 and used to provide an antenna or other component. This is particularly useful where the surface of the system-in-package module is curved, such as system-in-package module 700 (shown in FIG. 7.)

System-in-package module 100 can be manufactured following various methods that utilize different materials. Examples are shown in the following figures.

FIGS. 2A-2E illustrate a method of manufacturing a system-in-package module according to an embodiment of the present invention. In FIG. 2A, board 240 can include a number of layers (not shown) supporting interconnect paths that include a number of horizontal traces and vertical vias (not shown.) Traces 250 can be formed on top surface and a bottom surface of board 240. Contacts 260 can be formed on the top surface and the bottom surface of board 140.

In FIG. 2B, a number of components can be attached to a top surface of board 240. These components can be attached using surface-mount technology. These components can be soldered to contacts 260 during a reflow process. These components can include a wireless circuit 204, pin 220, and pin 230. Pin 220 can be attached to a top surface of board 240 at contact 262. Pin 230 can be attached to a top surface of board 240 at contact 264. Other integrated circuits, active components, passive components, electro-mechanical systems, or other components can be attached to board 240. In this example, these can be represented by integrated circuit 202. Wireless circuit 204 can be electrically connected to pin 220, pin 230, and integrated circuit 202 through interconnect paths in board 240.

In FIG. 2C, encapsulation 270 can be formed over the top surface of board 240. Encapsulation 270 can be over and substantially around wireless circuit 204. A top portion 280 of pin 220 can remain exposed above a top surface of encapsulation 270. A top portion 282 of pin 230 can remain exposed above a top surface of encapsulation 270. Solder 289 can be applied to top portion 280 and top portion 282. For example, solder paste can be dispensed on top portion 280 and top portion 282.

In FIG. 2D, adhesive layer 292 can be applied to a top surface of encapsulation 270. Top portion 280 and top portion 282 can remain exposed by adhesive layer 292. Antenna 290 can be placed on adhesive layer 292. Antenna 290 and pin 220, as well as antenna 290 and pin 230, can be soldered together other during a local reflow. This local reflow can help to laminate antenna 290, adhesive layer 292, and encapsulation 270 together.

In these and other embodiments of the present invention, various connections can be made to a system-in-package module. In FIG. 2E, connector 208 can be attached to contact 260 on the underside of system-in-package module 200.

In these and other embodiments of the present invention, an antenna, such as antenna 110 (shown in FIG. 1), antenna 290, and antenna 710 (shown in FIG. 7) can be attached to pins, such as pin 120 and pin 130 (shown in FIG. 1), pin 220 and pin 230, and pin 720 and pin 730 (shown in FIG. 7) in various ways. In the above example, top portion 280 of pin 220 and top portion 282 of pin 230 can remain exposed above encapsulation 270. In these and other embodiments of the present invention, encapsulation 270 can be over top portion 280 of pin 220 and top portion 282 of pin 230. A laser, chemical etch, or other process can be used to ablate the portion of encapsulation 270 over top portion 280 of pin 220 and top portion 282 of pin 230, thereby revealing top portion 280 of pin 220 and top portion 282 of pin 230. An example is shown in the following figure.

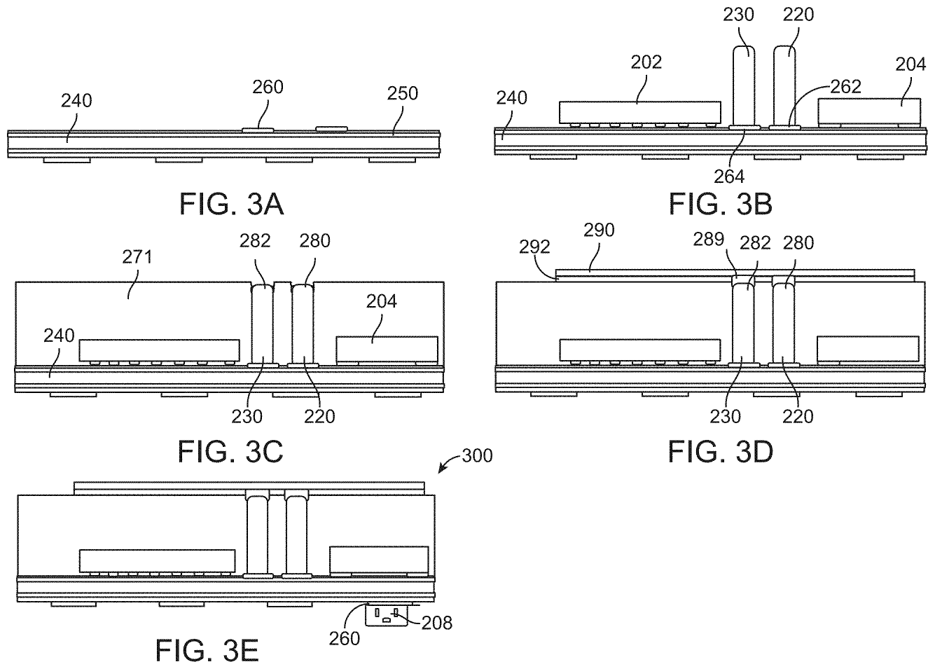

FIGS. 3A-3E illustrate a method of manufacturing a system-in-package module according to an embodiment of the present invention. In FIG. 3A, board 240 can include a number of layers (not shown) supporting interconnect paths that include a number of horizontal traces and vertical vias (not shown.) Traces 250 can be formed on top surface and a bottom surface of board 240. Contacts 260 can be formed on the top surface and the bottom surface of board 140.

In FIG. 3B, a number of components can be attached to a top surface of board 240. These components can be attached using surface-mount technology. These components can be soldered to contacts 260 during a reflow process. These components can include a wireless circuit 204, pin 220, and pin 230. Pin 220 can be attached to a top surface of board 240 at contact 262. Pin 230 can be attached to a top surface of board 240 at contact 264. Other integrated circuits, active components, passive components, electro-mechanical systems, or other components can be attached to board 240. In this example, these can be represented by integrated circuit 202. Wireless circuit 204 can be electrically connected to pin 220, pin 230, and integrated circuit 202 through interconnect paths in board 240.

In FIG. 3C, encapsulation 271 can be formed over the top surface of board 240. Encapsulation 271 can be over and substantially around wireless circuit 204. Encapsulation 271 can cover top portion 280 of pin 220 and top portion 282 of pin 230. The portion of encapsulation 270 over top portion 280 of pin 220 and top portion 282 of pin 230 can be removed or ablated. A laser, chemical etch, or other process can be used to ablate the portion of encapsulation 270 over top portion 280 of pin 220 and top portion 282 of pin 230, thereby revealing top portion 280 of pin 220 and top portion 282 of pin 230.

In FIG. 3D, solder 289 can be applied to top portion 280 of pin 230 and to top portion 282 of pin 220. For example, solder paste can be dispensed on top portion 280 and top portion 282. Adhesive layer 292 can be applied to a top surface of encapsulation 270. Applied solder 289 can remain exposed by adhesive layer 292. Antenna 290 can be placed on adhesive layer 292. Antenna 290 and pin 220, as well as antenna 290 and pin 230, can be soldered together other during a local reflow. This local reflow can help to laminate antenna 290, adhesive layer 292, and encapsulation 270 together.

In these and other embodiments of the present invention, various connections can be made to a system-in-package module. In FIG. 3E, connector 208 can be attached to contact 260 on the underside of system-in-package module 300.

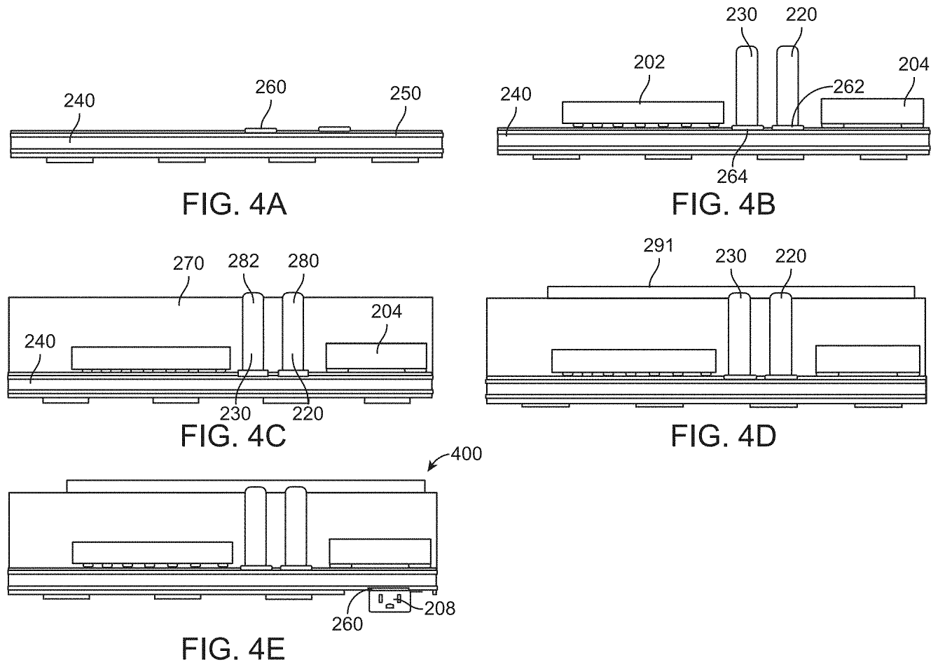

In these and other embodiments of the present invention, an antenna, such as antenna 110 (shown in FIG. 1), antenna 290, and antenna 710 (shown in FIG. 7) can be formed in various ways. In the example above, a copper foil layer can be used as antenna 290. Antenna 290 can be held in place using adhesive layer 292. Alternatively, an antenna, such as antenna 291 (shown in FIG. 4), can be formed using conductive ink, conductive epoxy paste, or other material. Antenna 291 can be formed using printing, such as pad printing, stencil printing, ink-jet printing, physical vapor deposition, plating, or method. Antenna 291 can be printed in a pattern optimized for wireless signal reception. An example is shown in the following figure.

FIGS. 4A-4E illustrate a method of manufacturing a system-in-package module according to an embodiment of the present invention. In FIG. 4A, board 240 can include a number of layers (not shown) supporting interconnect paths that include a number of horizontal traces and vertical vias (not shown.) Traces 250 can be formed on top surface and a bottom surface of board 240. Contacts 260 can be formed on the top surface and the bottom surface of board 140.

In FIG. 4B, a number of components can be attached to a top surface of board 240. These components can be attached using surface-mount technology. These components can be soldered to contacts 260 during a reflow process. These components can include a wireless circuit 204, pin 220, and pin 230. Pin 220 can be attached to a top surface of board 240 at contact 262. Pin 230 can be attached to a top surface of board 240 at contact 264. Other integrated circuits, active components, passive components, electro-mechanical systems, or other components can be attached to board 240. In this example, these can be represented by integrated circuit 202. Wireless circuit 204 can be electrically connected to pin 220, pin 230, and integrated circuit 202 through interconnect paths in board 240.

In FIG. 4C, encapsulation 270 can be formed over the top surface of board 240. Encapsulation 270 can be over and substantially around wireless circuit 204. A top portion 280 of pin 220 can remain exposed above a top surface of encapsulation 270. A top portion 282 of pin 230 can remain exposed above a top surface of encapsulation 270.

In FIG. 4D, antenna 291 can be formed. Antenna 291 can be formed of conductive ink, conductive epoxy paste, or other material. Antenna 291 can be formed using printing, such as pad printing, stencil printing, ink-jet printing, physical vapor deposition, plating, or method. Antenna 291 can be printed in a pattern optimized for wireless signal reception. Antenna 291 can be electrically connected to pin 220 and pin 230.

In these and other embodiments of the present invention, various connections can be made to a system-in-package module. In FIG. 4E, connector 208 can be attached to contact 260 on the underside of system-in-package module 400.

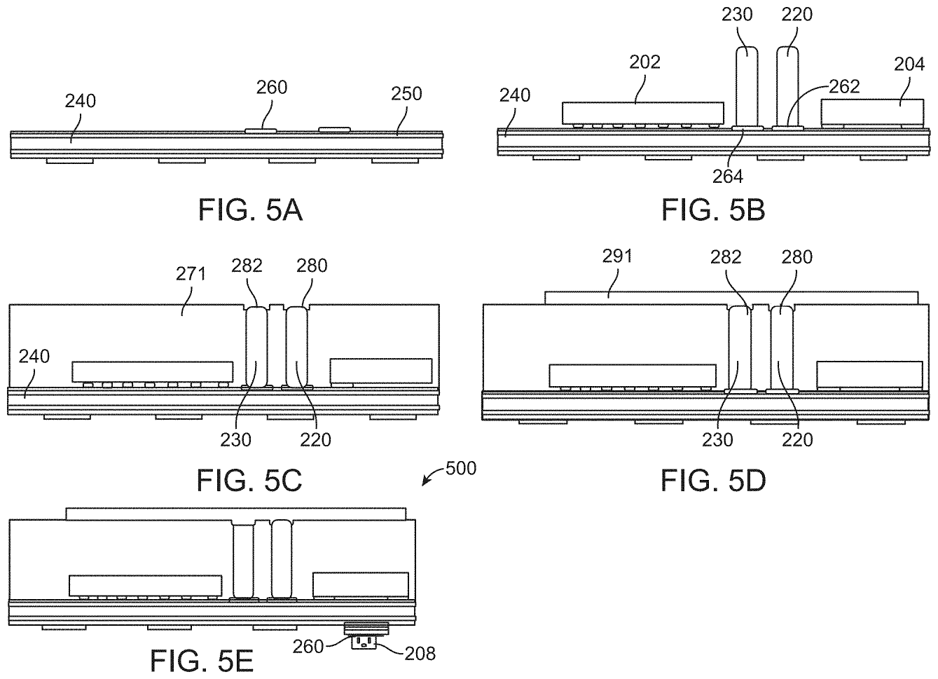

FIGS. 5A-5E illustrate a method of manufacturing a system-in-package module according to an embodiment of the present invention. In FIG. 5A, board 240 can include a number of layers (not shown) supporting interconnect paths that include a number of horizontal traces and vertical vias (not shown.) Traces 250 can be formed on top surface and a bottom surface of board 240. Contacts 260 can be formed on the top surface and the bottom surface of board 140.

In FIG. 5B, a number of components can be attached to a top surface of board 240. These components can be attached using surface-mount technology. These components can be soldered to contacts 260 during a reflow process. These components can include a wireless circuit 204, pin 220, and pin 230. Pin 220 can be attached to a top surface of board 240 at contact 262. Pin 230 can be attached to a top surface of board 240 at contact 264. Other integrated circuits, active components, passive components, electro-mechanical systems, or other components can be attached to board 240. In this example, these can be represented by integrated circuit 202. Wireless circuit 204 can be electrically connected to pin 220, pin 230, and integrated circuit 202 through interconnect paths in board 240.

In FIG. 5C, encapsulation 271 can be formed over the top surface of board 240. Encapsulation 271 can be over and substantially around wireless circuit 204. Encapsulation 271 can cover top portion 280 of pin 220 and top portion 282 of pin 230. After encapsulation 271 is cured, the portion of encapsulation 270 over top portion 280 of pin 220 and top portion 282 of pin 230 can be removed or ablated. A laser, chemical etch, or other process can be used to ablate the portion of encapsulation 270 over top portion 280 of pin 220 and top portion 282 of pin 230, thereby revealing top portion 280 of pin 220 and top portion 282 of pin 230.

In FIG. 5D, antenna 291 can be formed. Antenna 291 can be formed of conductive ink, conductive epoxy paste, or other material. Antenna 291 can be formed using printing, such as pad printing, stencil printing, ink-jet printing, physical vapor deposition, plating, or method. Antenna 291 can be printed in a pattern optimized for wireless signal reception. The ink, paste, or other material used to form antenna 291 can fill the trench formed by the ablation of encapsulation 271, thereby contacting top portion 280 of pin 220 and top portion 282 of pin 230.

In these and other embodiments of the present invention, various connections can be made to a system-in-package module. In FIG. 5E, connector 208 can be attached to contact 260 on the underside of system-in-package module 500.

System-in-package modules 200, 300, 400, and 500 can be manufactured using various materials. For example, antennas 290 and 291 can be formed in various ways. Antenna 290 (shown in FIG. 2D) can be formed of copper foil layer and attached to a surface of system-in-package module with adhesive layer 292 (shown in FIG. 2D.) Antenna 290 can be a rolled-annealed copper layer. Adhesive layer 292 can be a pressure-sensitive adhesive layer, a heat-activated film layer, a polyimide film|or other adhesive layer. Antenna 291 (shown in FIG. 4) can be formed using conductive epoxy paste, conductive ink, or other material. Antenna 291 can be formed using printing, such as pad printing, stencil printing, ink-jet printing, physical vapor deposition, plating, or method. Antennas 290 and 291 can be printed in a pattern optimized for wireless signal reception. Pin 220 and pin 230 can be formed as copper pins, though they can be formed of other materials, such as stainless steel, copper alloys, or other materials. A stack of molten solder or sinter drops can be used to form pin 220 and pin 230. A wire bond can be used to form pin 220 and pin 230. Encapsulations 270 and 271 can be formed of various materials. For example, encapsulation 270 and 271 can be formed of epoxy molding compounds. This material is particularly useful when antenna 290 or antenna 291 is printed on a surface of system-in-package module 100. Encapsulations 270 and 271 can be formed of a liquid crystal polymer. This material is particularly useful when antenna 290 or antenna 291 is plated on a surface of system-in-package module 200, 300, 400, or 500. Encapsulation 270 or encapsulation 271 can be formed using Laser Direct Structuring (LDS) and an epoxy molding compound. Antenna 290 or antenna 291 can be formed by activating a surface of encapsulation 270 or encapsulation 271 with a laser and then plating. Pin 220 and pin 230 can be attached to antenna 290 or antenna 291 in various ways. For example, encapsulation 270 can be formed such that a top portion of pin 220 and a top portion of pin 230 remain exposed. When antenna 290 or antenna 291 is formed, it can be physically and electrically connected to the top portion 280 of pin 220 and the top portion 282 of pin 230. Alternatively, encapsulation 271 can be formed such that the top portion 280 of pin 220 and the top portion 282 of pin 230 is covered by encapsulation 271. Encapsulation 271 over the top portion of each pin can be etched, laser ablated, or otherwise removed thereby leaving the top portion 280 of pin 220 and the top portion 282 of pin 230 exposed where they can be physically and electrically connected to the antenna 290 or antenna 291 when antenna 290 or antenna 291 is formed. While antenna 290 and antenna 291 are shown here, other structures, such as sensor electrodes, charging coils, transformers, shields, inductors, capacitors, resistors, and other components can be added to or formed on a surface of encapsulation 170.

These and other embodiments of the present invention can include other components, on a board, on a surface of encapsulation, or elsewhere on a system-in-package module. This inclusion can increase a functionality of system-in-package module. This inclusion can also save space in an electronic device when an included component replaces a separate component that would otherwise be needed. For example, sensor electrodes, charging coils, transformers, shields, inductors, capacitors, resistors, and other components can be formed on a board, on a surface of encapsulation, or elsewhere on a system-in-package module.

These and other embodiments of the present invention can also save space in an electronic device by providing system-in-package modules that have one or more surfaces that at least partially conform to an enclosure for the electronic device. These and other embodiments of the present invention can also save space in an electronic device by providing system-in-package modules that have one or more surfaces that at least partially conform to an interior surface, structure, partition, or other portion of an electronic device. Examples are shown in the following figures.

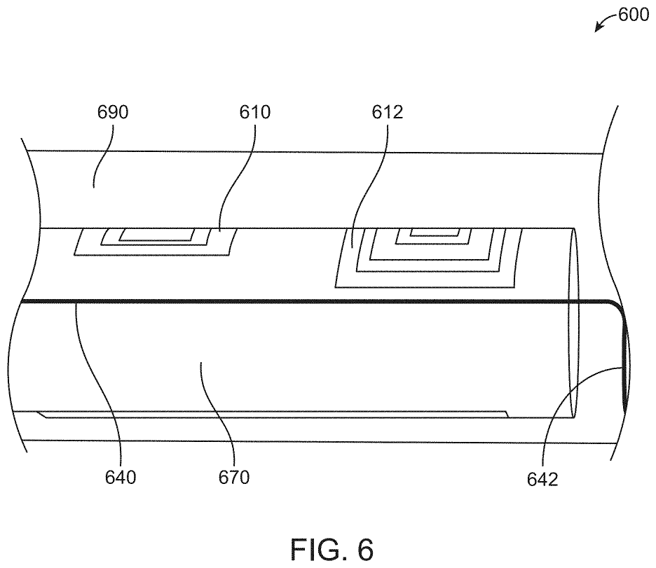

FIG. 6 illustrates a portion of an electronic device according to an embodiment of the present invention. In this example, board 640 can be a flexible circuit board. This flexible circuit board can be attached to a printed circuit board (not shown) to form a combined board 640. The flexible circuit board portion of combined board 640 can have tail portion 642 that can exit system-in-package module 600. Board 640 can be at least partially covered by molding layer or encapsulation 670. Encapsulation 670 can be similar to encapsulation 170 (shown in FIG. 1), encapsulation 270 (shown in FIG. 2), encapsulation 271 (shown in FIG. 3), and the other encapsulations shown here. A surface of encapsulation 670 can be curved to fit in portion 690 of an electronic device. Components, such as sensor electrode 610 and charging coil 612, can be formed on a surface of encapsulation 670. Sensor electrode 610 and charging coil 612, and other such components, can be electrically connected to board 640 through one or more pins, such as pin 120 and pin 130 (shown in FIG. 1), pin 220 and pin 230 (shown in FIG. 2), or any of the other pins shown here. Sensor electrode 610 and charging coil 612, and other such components, can be formed similar to antenna 110 (shown in FIG. 1), antenna 290 (shown in FIG. 2), or antenna 291 (shown in FIG. 4.) That is, they can be formed of a copper foil layer that is attached to a surface of system-in-package module with an adhesive layer. The copper foil layer can be a rolled-annealed copper layer. The adhesive layer can be a pressure-sensitive adhesive layer, a heat-activated film layer, a polyimide film|or other adhesive layer. They can be formed using conductive epoxy paste, conductive ink, or other material. Sensor electrode 610 and charging coil 612, and other such components can be formed using printing, such as pad printing, stencil printing, ink-jet printing, physical vapor deposition, plating, or method. Alternatively, sensor electrode 610 and charging coil 612, and other such components can be formed on a flexible circuit board (not shown.) This flexible circuit board can then be attached to a top surface of encapsulation 670 and curved to fit the curved top surface.

FIG. 7 is a simplified transparent view of a system-in-package module according to an embodiment of the present invention. In this example, a top surface of system-in-package module 700 can be curved to better fit in an electronic device, thereby saving space.

System-in-package module 700 can be formed on board 740. Board 740 can be a printed circuit board, flexible circuit board, or other appropriate substrate. Board 740 can be formed of multiple layers and can include ground planes, power planes, and electrical interconnect paths formed of horizontal traces and vertical vias (not shown.) One or more plated layers 750 can be formed on board 740. In this example, one or more plated layers 750 can form contact 764 and ground plane 760 on a top surface of board 740. Molding layer or encapsulation 770 can be formed over the top surface of board 740. A top surface of encapsulation 770 can be curved to better fit or at least approximately follow a contour of an enclosure or internal structure of an electronic device. Antenna 710 can be formed on a top surface of encapsulation 770.

Pin 720 and pin 730 can electrically connect antenna 710 to interconnect paths in board 740. Pin 720 can be used as a portion of a feeder path and can electrically connect to antenna 710 at location 712. Pin 720 can be soldered to contact 764 on a top surface of board 740. Contact 764 can in turn be connected to an interconnect path in board 740. Pin 730 can be used as a portion of a ground path and can electrically connect to antenna 710 at location 714. Pin 730 can be soldered to ground plane 760 at contact 762 on the top surface of board 740. Ground plane 760 can in turn be connected to interconnect paths and ground planes in board 740.

System-in-package module 700 can include additional functionality. For example, system-in-package module 700 can include one or more integrated circuits, one or more other passive or active components, one or more micro electro-mechanical systems, or other types of components. For example, system-in-package module 700 can include one or more integrated circuits including a wireless circuit. This wireless circuit can be a wireless receiver, wireless transmitter, wireless transceiver, or other integrated circuit. These additional components are represented here as components 780, which are external to encapsulation 770, though some or all of these components can be located within encapsulation 770.

System-in-package module 700 can have one or more curved surfaces. For example, a top surface of encapsulation 770 can be curved. The curvature can be along the major axis as shown, though in other embodiments of the present invention other curvatures can be used. Pin 720 and pin 730 can be aligned with the axis of curvature. Accordingly, encapsulation 770 can have the same depth at the location of pin 720 as at the location of pin 730, such that when pin 720 and pin 730 have the same length, a top portion of pin 720 and a top portion of pin 730 can have the same positioning relative to a surface of encapsulation 770. In some circumstances, pin 720 and pin 730 can be offset with each other relative to an axis of curvature. To compensate, pin 720 and pin 730 can have different lengths. The difference in length in pins can compensate for a difference in encapsulation depth at the location of pin 720 and the location of pin 730.

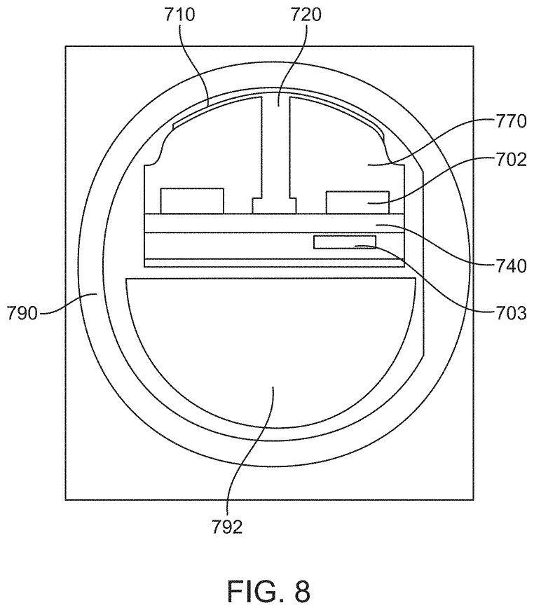

FIG. 8 illustrates a cutaway side view of an electronic device incorporating the system-in-package module of FIG. 7. In this example, antenna 710 can be formed on a top surface of encapsulation 770. This can save space inside the electronic device housed by enclosure 790. For example, region 792, which can ordinarily be consumed by antenna 710, can be utilized to include additional functionality, to decrease a size of the electronic device, or a combination thereof.

System-in-package module 700 can include board 740. Board 740 can support components 702 and 703 on a top and bottom surface of board 740. Pin 720 can electrically connect antenna 710 to board 740.

System-in-package module 700 can be manufactured using various materials. For example, antenna 710 can be formed in various ways. Antenna 710 can be formed of a copper foil layer and attached to a surface of system-in-package module with adhesive layer 292 (shown in FIG. 2D.) The copper foil layer can be a rolled-annealed copper layer. Adhesive layer 292 can be a pressure-sensitive adhesive layer, a heat-activated film layer, a polyimide film|or other adhesive layer. Antenna 710 can be formed using conductive epoxy paste. Antenna 710 can be formed using printing, such as pad printing, stencil printing, ink-jet printing, physical vapor deposition, plating, or method. Antenna 710 can be printed in a pattern optimized for wireless signal reception. Alternatively, antenna 710 and other such components can be formed on a flexible circuit board (not shown.) This flexible circuit board can then be attached to a top surface of encapsulation 770 and curved to fit the curved top surface. Pin 720 and pin 730 can be formed as copper pins, though they can be formed of other materials, such as stainless steel, copper alloys, or other materials. A stack of molten solder or sinter drops can be used to form pin 720 and pin 730. A wire bond can be used to form pin 720 and pin 730. Encapsulation 770 can be formed of various materials. For example, encapsulation 770 can be formed of epoxy molding compounds. This material is particularly useful when antenna 710 is printed on a surface of system-in-package module 700. Encapsulation 770 can be formed of a liquid crystal polymer. This material is particularly useful when antenna 710 is plated on a surface of system-in-package module. Encapsulation 770 can be formed using Laser Direct Structuring (LDS) and an epoxy molding compound. Antenna 710 can then be formed by activating a surface of encapsulation 770 with a laser and plating. Pin 720 and pin 730 can be attached to antenna 710 in various ways. For example, encapsulation 770 can be formed such that a top portion of pin and a top portion of pin 730 remains exposed. When antenna 710 is formed, it can be physically and electrically connected to the top portion of pin 720 and the top portion of pin 730. Alternatively, encapsulation 770 can be formed such that the top portion of pin 720 and the top portion of pin 730 is covered by encapsulation 770. Encapsulation 770 over the top portion of each pin can be etched or laser ablated, thereby leaving the top portion of pin 720 and the top portion of pin 730 exposed where they can be physically and electrically connected to the antenna 710 when antenna 710 is formed. While antenna 710 is shown here, other structures, such as sensor electrodes, charging coils, transformers, shields, inductors, capacitors, resistors, and other components can be formed on a surface of encapsulation 770.

These and other embodiments of the present invention can include other components, on board 740, on a surface of encapsulation 770, or elsewhere on system-in-package module 700. This inclusion can increase a functionality of system-in-package module 700. This inclusion can also save space in an electronic device when an included component replaces a separate component that would otherwise be needed. For example, sensor electrodes, charging coils, transformers, shields, inductors, capacitors, resistors, and other components can be formed on a board, on a surface of an encapsulation, or elsewhere on system-in-package module 700. Two or more encapsulation layers can be stacked to bring even further functionality to system-in-package module 700. For example, first encapsulation 770 can be formed over board 740. A shield or other component (not shown) can be formed on a surface of first encapsulation 770. Additional electronic components, such as resistors, capacitors, active components, integrated circuits, or others can be added to or formed on the surface of first encapsulation 770. Connections between board 740 and these components can be made through pin 720 and pin 730. A second encapsulation (not shown) can be formed over first encapsulation 770. An antenna or other component (not shown) can be formed on a surface of the second encapsulation. Additional electronic components, such as resistors, capacitors, active components, integrated circuits, or others (not shown) can be added to or formed on the surface of the second encapsulation. Connections between board 740 and these components, and between these components and components on the surface of the first encapsulation, can be made through pins (not shown.) A surface of first encapsulation 770 can be flat or planar, or it can be curved. A surface of the second encapsulation can be flat or planar, or it can be curved. Stacking of encapsulations can be facilitated by employing a thermoset plastic for at least first encapsulation 770, since this material might not re-melt when the second encapsulation is formed.

It should be noted that while the structures and methods described above are well-suited to forming system-in-package modules, in other embodiments of the present invention, other types of electronic devices can be formed using these techniques. Embodiments of the present invention can be used at different levels in the manufacturing of a system-in-package module. For example, a system-in-package module can be formed of one or more other sub-modules, and these embodiments of the present invention can be used in one or more of these sub-modules. The system-in-package module itself can be formed by employing one or more embodiments of the present invention.

In various embodiments of the present invention, pins and other conductive portions of the system-in-package modules can be formed by stamping, metal-injection molding, machining, micro-machining, 3-D printing, or other manufacturing process. The conductive portions can be formed of stainless steel, steel, copper, copper titanium, aluminum, phosphor bronze, or other material or combination of materials. They can be plated or coated with nickel, gold, or other material. The nonconductive portions can be formed using injection, insert, overmolding, or other molding, 3-D printing, machining, or other manufacturing process. The nonconductive portions can be formed of silicon or silicone, rubber, hard rubber, plastic, nylon, liquid-crystal polymers, or other nonconductive material or combination of materials. The printed circuit board or other appropriate substrates used can be formed of FR-4, BT or other material. Printed circuit boards can be replaced by other substrates, such as flexible circuit boards, in many embodiments of the present invention, while flexible circuit boards can be replaced by printed circuit boards in these and other embodiments of the present invention.

These and other embodiments of the present invention can provide system-in-package modules that can be located in various types of devices, such as portable computing devices, tablet computers, desktop computers, laptops, all-in-one computers, wearable computing devices, smart phones, storage devices, portable media players, navigation systems, headphones, earbuds, speakers, or other audio components, monitors, power supplies, adapters, remote control devices, chargers, and other devices.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A system-in-package module comprising:
a board having a top surface;
an integrated circuit attached to a first plurality of contacts on the top surface of the board;
a first vertical interconnect pin connected to a first contact on the top surface of the board;
a second vertical interconnect pin connected to a second contact on the top surface of the board;
an encapsulation on the top surface of the board, over the integrated circuit, and at least substantially around the first vertical interconnect pin and the second vertical interconnect pin; and
an antenna on a top surface of the encapsulation, such that the encapsulation is between the antenna and the top surface of the board, the antenna connected to the first vertical interconnect pin and the second vertical interconnect pin.

2. The system-in-package module of claim 1 wherein the antenna is formed by printing.

3. The system-in-package module of claim 1 wherein the antenna is a copper foil lamination.

4. The system-in-package module of claim 1 wherein the encapsulation is formed of an epoxy molding compound.

5. The system-in-package module of claim 1 wherein the integrated circuit is a wireless transceiver.

6. The system-in-package module of claim 5 wherein the board is a printed circuit board.

7. The system-in-package module of claim 1 wherein a top surface of the encapsulation is flat.

8. The system-in-package module of claim 1 wherein a top surface of the encapsulation is curved.

9. The system-in-package module of claim 1 wherein the board comprises a conducive path connecting a contact of the integrated circuit to the first vertical interconnect pin.

10. The system-in-package module of claim 1 wherein the antenna is formed by physical vapor deposition and includes a low-frequency shielding layer.

11. A system-in-package module comprising:
a board having a top surface;
an integrated circuit attached to a first plurality of contacts on the top surface of the board;
an encapsulation on the top surface of the board and over the integrated circuit;
a first vertical interconnect pin connected to a first contact on the top surface of the board and extending to near a top surface of the encapsulation;
a second vertical interconnect pin connected to a first contact on the top surface of the board and extending to near a top surface of the encapsulation;
wherein the encapsulation comprises a first trench formed over a top surface of the first vertical interconnect pin and a second trench formed over a top surface of the second vertical interconnect pin; and
an antenna on a top surface of the encapsulation, such that the encapsulation is between the antenna and the top surface of the board, the antenna in the first trench and connected to the first vertical interconnect pin and in the second trench and connected to the second vertical interconnect pin.

12. The system-in-package module of claim 11 wherein the antenna is formed by printing.

13. The system-in-package module of claim 11 wherein the antenna is a copper foil lamination.

14. The system-in-package module of claim 11 wherein the encapsulation is formed of an epoxy molding compound.

15. The system-in-package module of claim 14 wherein a top surface of the encapsulation is curved.

16. A system-in-package module comprising:
a board having a top surface;
an integrated circuit attached to a first plurality of contacts on the top surface of the board;
an encapsulation on the top surface of the board and over the integrated circuit;
a first vertical interconnect pin connected to a first contact on the top surface of the board and extending beyond a top surface of the encapsulation;
a second vertical interconnect pin connected to a first contact on the top surface of the board and extending beyond a top surface of the encapsulation; and
an antenna on a top surface of the encapsulation, such that the encapsulation is between the antenna and the top surface of the board, the antenna connected to the first vertical interconnect pin and further connected to the second vertical interconnect pin.

17. The system-in-package module of claim 16 wherein the antenna is formed by printing.

18. The system-in-package module of claim 16 wherein the antenna is a copper foil lamination.

19. The system-in-package module of claim 16 wherein the encapsulation is formed of an epoxy molding compound.

20. The system-in-package module of claim 19 wherein a top surface of the encapsulation is curved.
